(19) United States
(12) Patent Application Publication
(10) Pub. No.: US 2026/0331195 A1
(43) Pub. Date: Oct. 22, 2026

(54) TRACK AND HOLD CIRCUIT

(71) Applicant: Vitalthings UWB AS, Trondheim (NO)

(72) Inventor: Jørgen Andreas MICHAELSEN, Trondheim (NO)

(73) Assignee: Vitalthings UWB AS, Trondheim (NO)

(21) Appl. No.: 19/109,421

(22) PCT Filed: Aug. 16, 2023
(86) PCT No.: PCT/EP2023/072625

§ 371 Date: Mar. 6, 2025

(30) Foreign Application Priority Data
Sep. 7, 2022 (GB) 2213088.4

(51) Int. Cl. G11C 27/02; H03M 1/12

(52) U.S. Cl. CPC G11C 27/02; H03M 1/124

(57) ABSTRACT

A track and hold circuit (100) for sampling an input signal, the track and hold circuit (100) comprising a first stage (200) and a second stage (300) and being arranged to operate alternately in a track mode and a hold mode. The first stage (200) is arranged to generate a constant output voltage at a first node in the hold mode and to generate the constant output voltage modulated by the input signal at the first node in the track mode. The second stage (300) comprises a sampling capacitor having a first side connected to the first node and a second side connected to a bias voltage through a sampling switch. A sampling output is provided at a sampling node between the sampling capacitor and the sampling switch. In the track mode, the sampling switch is closed and the voltage across the sampling capacitor varies as the input signal varies. In the hold mode, the sampling switch is open, the voltage across the sampling capacitor becomes fixed, and the sampling output becomes set based on the voltage at the node and the fixed voltage across the sampling capacitor.

### BACKGROUND OF THE INVENTION

This invention relates to a track and hold circuit for high speed sampling of signals.

Sampling of a time-varying signal is typically performed using a clocked switch with a capacitor to hold the signal when the switch is off. In other words, while the switch is closed, the output of the clocked switch tracks the input, and when the switch is open, the last value of the input is held on the capacitor. In some radio architectures, subsampling a band-limited signal is preferable to sampling a down-mixed signal. This requires a sampling circuit capable of processing the bandpass signal which may be at a high frequency. Therefore a high speed sampling circuit is required.

To enable sufficiently fast sampling, a track and hold circuit can be employed to track a time-varying input signal, and then to hold or sample the input signal at a particular time point. This ‘held’ value may be stored, e.g. in a capacitor, which may act as a buffer while processing of the held value takes place, e.g. using an external component such as an analogue to digital converter (ADC). In other words, during “hold”, an ADC can perform conversion of the sampled analogue signal value to the digital domain. Track and hold is typically performed using a sampling switch, turned on and off at a particular frequency. When the switch is on, the input signal is passed through the switch to the capacitor and the output (taken from the capacitor) tracks the input. When the switch is off, the input signal is blocked (disconnected) from the capacitor which then holds the last value of the input signal while processing takes place.

The present invention provides an alternative approach.

### SUMMARY OF THE INVENTION

From a first aspect, the invention provides a track and hold circuit for sampling an input signal, the track and hold circuit comprising a first stage and a second stage;
wherein the track and hold circuit is arranged to operate alternately in a track mode and a hold mode;
wherein in the hold mode, the first stage is arranged to generate a constant output voltage at a first node;
wherein in the track mode, the first stage is arranged to generate the constant output voltage modulated by the input signal at the first node;
wherein the second stage comprises:
   a first sampling capacitor having a first side connected to the first node and a second side connected to a first bias voltage through a first sampling switch;
wherein a first sampling output is provided at a first sampling node between the first sampling capacitor and the first sampling switch;
wherein, in the track mode, the first sampling switch is closed and the voltage across the first sampling capacitor varies as the input signal varies; and
wherein, in the hold mode, the first sampling switch is open, the voltage across the first sampling capacitor becomes fixed, and the first sampling output becomes set based on the voltage at the first node and the fixed voltage across the first sampling capacitor.

Thus it will be seen that, in accordance with the invention there is provided a two stage track and hold circuit arranged to track an input signal in a first mode (when the first sampling switch is closed), and to provide a held output signal in a second mode (when the first sampling switch is open). The track and hold circuit of the present invention advantageously avoids the use of a sampling switch provided in series with the input signal. In this way, loss that typically occurs across the switch can be reduced without increasing the width of the switch, which would provide unwanted additional capacitance and charge injection, requiring a larger capacitor in the track and hold circuit.

In some embodiments, the second stage may comprise a second sampling capacitor having a first side connected to the first node and a second side connected to a second bias voltage through a second sampling switch. A second sampling output may be provided at a second sampling node between the second sampling capacitor and the second sampling switch. In the track mode, the second sampling switch is closed and the voltage across the second sampling capacitor varies as the input signal varies; and, in the hold mode, the second sampling switch is open, the voltage across the second sampling capacitor becomes fixed, and the second sampling output becomes set based on the voltage at the first node and the fixed voltage across the second sampling capacitor

In such embodiments, the tracked input signal may thus be stored on two separate sampling capacitors, which may be connected, at their respective second sides, to first and second bias voltages. The first and second bias voltages may be provided by a voltage rail or a voltage node. Preferably, the first and second bias voltages are fixed or constant voltages. For example, the first sampling switch may be configured such that a first side of the switch is connected to the second side of the first sampling capacitor and the second side of the switch is connected to a first bias voltage node or first bias voltage rail (i.e. a stable voltage node that is able to supply or sink current so as to maintain its bias voltage at a stable and consistent level).

The second sampling switch may be configured such that a first side of the switch is connected to the second side of the second sampling capacitor and the second side of the switch is connected to a second bias voltage node or second bias voltage rail (i.e. a stable voltage node that is able to supply or sink current so as to maintain its bias voltage it a stable and consistent level). Thus, when the first sampling switch is closed, the second side of the first sampling capacitor may be connected to a first bias voltage and when the second sampling switch is closed, the second side of the second sampling capacitor may be connected to a second bias voltage. These bias voltages may be selected for other circuit components.

In some embodiments, the first sampling output may be connected to a first amplifier such that the output of the first amplifier is dependent on the first sampling output. The first amplifier may be connected such that it provides an output signal at a third node. In some such embodiments, the first amplifier may be a first transistor, arranged such that it receives the first sampling output at its gate. Thus, in some embodiments, the first sampling output is connected to the gate of the first transistor. The first transistor may be a PMOS transistor having a positive rail connected to its source and the third node connected to its drain. Alternatively, the first transistor may be an NMOS transistor having a negative rail connected to its source and the third node connected to its drain.

In some embodiments, the second sampling output may be connected to a second amplifier such that the output of the second amplifier is dependent on the second sampling output. The second amplifier may be connected such that it provides an output signal at the third node. Providing the output signal of both the first amplifier and the second amplifier at the same third node may provide an output signal at the third node of greater amplitude than may be achieved using a single amplifier at either of the first or second sampling outputs. In some such embodiments, the second amplifier may be a second transistor, arranged such that it receives the second sampling output at its gate. Thus, in some embodiments, the second sampling output is connected to the gate of the second transistor. The second transistor may be a PMOS transistor having a positive rail connected to its source and the third node connected to its drain. Alternatively, the second transistor may be an NMOS transistor having a negative rail connected to its source and the third node connected to its drain.

In some embodiments, the first sampling output may be connected to the gate of a PMOS transistor and the second sampling output may be connected to the gate of an NMOS transistor. The PMOS transistor may be connected such that the output of the PMOS transistor at a third node is dependent on the first sampling output and the NMOS transistor may be connected such that the output of the NMOS transistor at the third node is dependent on the second sampling output. The NMOS transistor may be connected such that a negative rail is connected to its source and the third node is connected to its drain. The PMOS transistor may be connected such that a positive rail is connected to its source and the third node is connected to its drain.

Providing the output signals of both the NMOS transistor and PMOS transistor at the at the same third node may allow an output signal to be generated at the third node of greater amplitude than may be achieved using a single NMOS or PMOS transistor to amplify the first and/or second sampling outputs. The two transistors effectively work together. As the NMOS transistor is turned more ‘off', the PMOS transistor will be turned more 'on’ and vice versa, thereby adjusting the current draws of both transistors in opposite ways and therefore shifting the output voltage at the third node by twice as much as if a single transistor were used.

In some embodiments the first stage may comprise a first branch and a second branch, the first and second branches being current paths between a second node and the first node and being in operation alternately. The first branch may be arranged to generate the constant output voltage at the first node. The second branch may be arranged to generate the constant output voltage modulated by the input signal at the first node. This arrangement provides a convenient way to produce the required voltage at the first node. The two branches are operated alternately so that the voltage at the first node is only modulated by the input voltage when the second branch is in operation, i.e. when the circuit is in track mode and the sampling switch (or switches) is (are) closed. When the sampling switch(es) is/are open, the first branch is in operation and the circuit is in hold mode and the voltage at the first node is just the constant output voltage without any modulation by the input signal.

In some embodiments, the first branch of the track and hold circuit and the second branch of the track and hold circuit may be operated alternately in response to a clock signal from an external clock source. For example, the first branch and the second branch may be connected alternately to the first node in response to a clock signal received at the track and hold circuit from an external clock source. It will be understood that ‘connected’ is meant in the sense of electrical connection, e.g. that a current can flow between two connected components. Thus, if the first branch is in operation, it is effectively connected to the first node, such that current may flow to the first node through the first branch of the track and hold circuit. Similarly, if the first branch is not in operation, it is effectively disconnected from the first node, such that current does not flow to the first node through the first branch of the track and hold circuit. In the same way, if the second branch is in operation, it is effectively connected to the first node, such that current may flow to the first node through the second branch of the track and hold circuit. Similarly, if the second branch is not in operation, it is effectively disconnected from the first node, such that current does not flow to the first node through the second branch of the track and hold circuit.

The clock signal may have at least two states, e.g., the clock signal may be high or low. In some such embodiments, when the clock signal is high, the second branch may be in operation, e.g. it may be connected to the first node, and the first branch is not in operation. When the clock signal is low, the first branch may be in operation, e.g. it may be connected to the first node and the second branch may not be connected to the first node.

In some embodiments, the clock signal may be a square wave signal. The square wave signal may have a predetermined frequency and duty cycle selected to allow the input signal to be sampled at a desired sampling rate, e.g. having a predetermined sampling interval between samples. For example, in cases where samples are required at the first sampling output (and/or the second sampling output, if present) only infrequently, the square wave signal may have a low frequency. In cases where samples are required more frequently, the square wave signal may have a high frequency.

The duty cycle of the clock may be adjusted to balance the time that each stage of the circuit has for operation. Each stage may have its own requirements for time. For example, if an amplifier is used to amplify the output in the second stage, that amplifier may need time to ramp up the output signal to a higher level. Therefore it may be advantageous to adjust the duty cycle of the clock to spend more time in hold mode than in track mode. After switching to track mode, the first stage may also need some time to settle and so the duty cycle also needs to allow a certain minimum time for the track mode. Therefore, in some embodiments the duty cycle of the clock may be 50:50 such that the track mode and hold mode have equal time. In other embodiments the duty cycle may be set such that the hold mode has a longer duration than the track mode. In some embodiments the duty cycle may be set such that the hold mode is no more than twice the length of the track mode.

In some embodiments, the first branch and the second branch may each comprise a respective “clocking” transistor, arranged to receive a signal based on the clock signal at their respective gates. A first clocking transistor may be connected on the first branch, e.g., it may be arranged such that the first branch is connected to both the source and drain of the first clocking transistor. A second clocking transistor may be connected on the second branch, e.g., arranged such that the second branch is connected to both the source and drain of the second clocking transistor. The first clocking transistor may be arranged to receive the clock signal at its gate, and the second clocking transistor may be arranged to receive an inverted clock signal at its gate. In this way the operation of the first and second branches can be controlled using a single clock source. Furthermore, by clocking the first branch and the second branch with opposite clock signals, this arrangement advantageously ensures that only one of the first branch and the second branch is in operation at a time, and thus only one branch is generating a voltage at the first node at a given time. In some embodiments, the clocking transistors may be PMOS transistors.

In some embodiments, the first sampling switch (and/or the second sampling switch, if present) may be clocked using the same clock signal as the first branch and the second branch, such that the first sampling switch (and/or the second sampling switch, if present) is open when the clock is high, and is closed when the clock is low. This ensures that a voltage is only varied across the first sampling capacitor (and/or the second sampling capacitor, if present) when the second branch is in operation. In some embodiments having first and second sampling switches, the first and second sampling switches may be clocked using the same clock signal, such that both sampling switches are open when the clock signal is low, and such that both sampling switches are closed when the clock signal is high. This ensures that the first sampling output and the second sampling output become set simultaneously, based on the voltage at the first node and the fixed voltage across the first and second sampling capacitors respectively. This may be particularly important in embodiments where the first and second sampling outputs are provided to a common third node (e.g. after being provided to respective amplifiers) as both sampling capacitors will then reflect exactly the same sampling time.

In some embodiments, the first stage of the sampling circuit may comprise a feedback element. The feedback element may be arranged to compensate for the variation in current draw caused by variations in the input signal. In other words, the feedback element may be arranged to improve linearity in the first stage.

The second node may be a positive supply rail (or other supply of current), e.g. a high rail, arranged to act as a voltage source for the sampling circuit. The second node may be connected to the first and second branches via a first current controlling transistor. In some embodiments, the current controlling transistor may be a PMOS transistor connected between the second node and the first and second branches of the first stage of the sampling circuit, e.g., such that its source terminal is connected to the second node and such that its drain terminal is connected to the first and second branches. This first current controlling transistor may allow the sampling circuit to be powered on or off in response to the presence of a voltage received at the gate of the first current controlling transistor, and may also allow the current through the first and second branches to be controlled by varying a first biasing voltage applied at the gate of the first current controlling transistor.

In some embodiments, the first branch, the second branch, and the first node are connected to ground or to a negative supply rail (or other current sink), e.g., a low rail, via a second current controlling transistor. The second current controlling transistor may be an NMOS transistor connected between the current sink and the first and second branches of the sampling circuit. In this way the first and second branches may be connected between an “upstream” second node (which may be a supply of current), and a “downstream” current sink, e.g., ground. The terms “upstream” and “downstream” here refer to the direction of flow of DC current from a positive supply rail (or other supply of current) to ground or a low rail (or other sink of current). In some such embodiments, the source terminal of the NMOS transistor may be connected to the current sink, and its drain terminal may be connected to the first and second branches of the first stage of the track and hold circuit. The gate of the NMOS transistor may be connected to a second biasing voltage that may be varied to set the current through the first and second branches.

In some embodiments, the first branch of the first stage may comprise means for receiving a common mode voltage, e.g., from a common mode voltage source. The means for receiving the common mode voltage may be a first biasing part connected on the first branch of the first stage of the track and hold circuit. The first biasing part may be a first biasing transistor connected on the first branch of the track and hold circuit. The first biasing transistor may be configured to receive the common mode voltage at its gate, e.g., such that the first branch may be controlled based on the common mode voltage. In some such embodiments, the first biasing transistor may be connected such that the first branch is connected to both the source and drain of the first biasing transistor, and such that the gate of the transistor is arranged to receive the common mode voltage. In some embodiments, the first biasing transistor may be an NMOS transistor.

The first stage of the track and hold circuit may comprise means for receiving the input signal from an external source. In some embodiments, the means for receiving the input signal may be a biasing part connected between the second branch of the track and hold circuit and a source of the input signal. The biasing part may be a second biasing transistor connected on the first branch of the track and hold circuit. The second biasing transistor may be configured to receive the common mode voltage at its gate, e.g., such that the second branch may be controlled based on the input signal. In some such embodiments, the second biasing transistor may be connected such that the second branch is connected to both the source and drain of the second biasing transistor, and such that the gate of the second biasing transistor is arranged to receive the input signal. In some embodiments, the transistor may be an NMOS transistor.

In some embodiments in which the first branch is arranged to receive a common mode voltage, the second biasing part may be arranged to receive the common mode voltage in addition to the input signal. For example, in embodiments in which the second biasing part is a second biasing transistor, the second biasing transistor may be arranged to receive the sum of the common mode voltage and the input signal at its gate.

In some embodiments, the input signal may be an analogue voltage, for example a time-varying analogue voltage.

From an alternative aspect, the invention provides a sampling circuit for sampling an input signal, the sampling circuit comprising a first stage and a second stage;
wherein the first stage comprises a first branch and a second branch, the first and second branches being current paths between a first node and a second node and being in operation alternately;
wherein the first branch is arranged to generate a constant output voltage at the second node;
wherein the second branch is arranged to generate the constant output voltage modulated by the input signal at the second node;
wherein the second stage comprises:
   a first sampling capacitor having a first side connected to the second node and a second side connected to a first bias voltage through a first sampling switch;
wherein a first sampling output is provided at a first sampling node between the first sampling capacitor and the first sampling switch;
wherein, when the first sampling switch is closed, the second branch is in operation, and the voltage across the first sampling capacitor varies as the input signal varies; and
wherein, when the first sampling switch is open, the first branch is in operation, the voltage across the first sampling capacitor becomes fixed, and the first sampling output becomes set based on the voltage at the second node and the fixed voltage across the first sampling capacitor.

It will be appreciated that all of the preferred and optional features described above in relation to the first aspect can also be applied to this alternative aspect.

Features of any aspect or embodiment described herein may, wherever appropriate, be applied to any other aspect or embodiment described herein.

Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic representation of a track and hold circuit according to the present invention;

FIG. 2 is a schematic representation of a first section of a track and hold circuit according to the present invention;

FIG. 3 is a schematic representation of a second section of a track and hold circuit according to the present invention; and

FIG. 4 is a schematic representation of an alternative implementation of a second section of a track and hold circuit according to the present invention.

### DETAILED DESCRIPTION

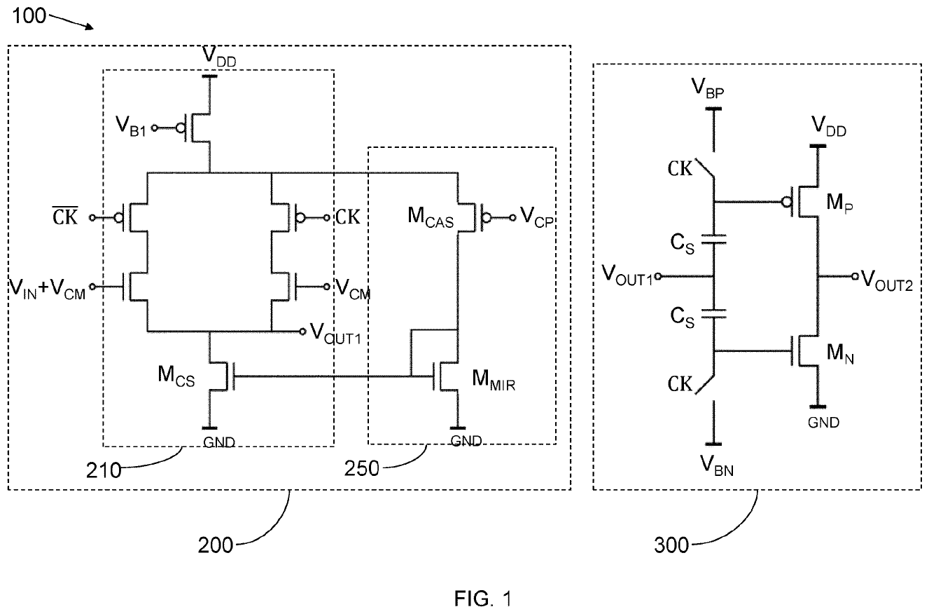

FIG. 1 shows a track and hold circuit 100 according to an embodiment of the present invention. The track and hold circuit 100 includes a first stage 200, and a second stage 300.

The first stage 200 comprises a first section 210 for sampling an input signal V_{IN}, such as a time varying analogue signal and, in some embodiments, further comprising a feedback section 250 used to provide additional gain in the first stage 200.

The first stage 200 can be placed in one of two states or modes. In a first state (track mode), the first stage 200 is configured to track the input signal V_{IN}, i.e. to provide an output signal V_{OUT1} that tracks the input signal V_{IN} with an added common mode voltage V_{CM}. Thus, in the first state, the first stage 200 outputs a voltage at the first node (V_{OUT1}) based on the common mode voltage modulated by the input signal V_{IN}. In the second state (hold mode), the first stage 200 is configured such that the output signal V_{OUT1} does not track the input signal, and instead the output signal V_{OUT1} is based just on the common mode voltage V_{CM}. The second stage 300 is configured to receive the output signal of the first stage 200 (V_{OUT1}), and to either allow the voltages across the sampling capacitors C_{S} to vary (in the first state or track mode), or to fix the voltage across the sampling capacitors C_{S} (in the second state or hold mode). In the second mode (hold mode), the second stage 300 provides an amplified signal V_{OUT2} based on the magnitude of the input voltage V_{IN} at the time that the sampling switches were opened.

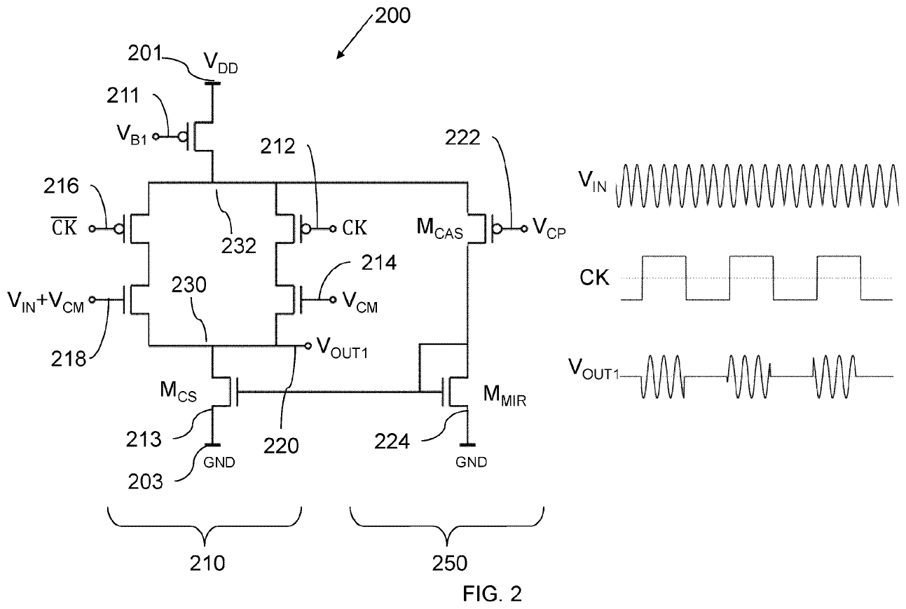

FIG. 2 shows the first stage 200 of the track and hold circuit 100 in more detail. The first section 210 of the first stage 200 can be seen to comprise two parallel branches connected between a PMOS transistor 211, connected to a positive supply rail 201, and an NMOS transistor 213 connected to a negative supply rail 203. The PMOS transistor 211 and the NMOS transistor 213 serve to set the biasing current through the two parallel branches of the first stage 200, but do not otherwise actively contribute to the track and hold function of the track and hold circuit 100. The first stage 200 of the track and hold circuit 100 can also be seen to comprise an output terminal 220, arranged downstream from the two parallel branches (i.e. further from the positive rail 201) and connected to both of the parallel branches.

Each branch of the first stage 200 comprises two transistors: a first transistor (referred to herein as a clocking part) with its gate connected to receive a signal from a clock source, and a second transistor (referred to herein as a biasing part) with its gate connected to receive one of two biasing voltages. As will be described in more detail below, the two branches act as alternative current paths, such that current may flow from the positive rail 201 to the negative rail 203 through either one of the two branches of the first stage 200 alternately, depending on the signal from the clock source.

The first branch comprises a first clocking part in the form of a PMOS transistor 212 with its gate connected to receive a clock signal CK from a clock source (not shown in FIG. 2), and a first biasing part in the form of an NMOS transistor 214 with its gate connected to a bias voltage, shown in FIG. 2 as a common mode voltage V_{CM}. In the example shown in FIG. 2, the clock signal CK takes the form of a square wave with a 50% duty cycle, however it will be appreciated that the present disclosure is not so limited, and that any clock signal having at least two states could instead be used. The first branch connects a first node 230 (which is also the first stage output V_{OUT1}) with a second node 232.

The second branch comprises a second clocking part in the form of a PMOS transistor 216 with its gate connected to an inverted output of the clock source, i.e. arranged to receive the inverse C̅K̅ of the clock signal, and a second biasing part in the form of an NMOS transistor 218 with its gate connected such that it receives the sum of the common mode voltage V_{CM} and the time varying input signal V_{IN} which is to be sampled. The second branch also connects the first node 230 with the second node 232.

By controlling the clock signal CK applied at the gate of the clocking transistors 212, 216, current may be made to flow from the positive rail 201 through either the first or second branch, i.e. through either of the first biasing part 214 or the second biasing part 218. This causes the output V_{OUT1} provided at the output terminal 220 (and the first node 230) to vary depending on whether the clock signal CK is logic high or logic low.

When the clock signal CK is logic low, current passes through the first branch of the circuit, such that it is dependent on the biasing voltage V_{CM} at the first biasing part 214. This effectively causes V_{CM} to be tracked, although as V_{CM} is constant, the output voltage at first node 230 is also constant in this mode, Thus V_{OUT1}∝V_{CM}.

When the clock is logic high however, current passes through the second branch of the circuit, such that the signal provided at the output 220 of the first stage (and at first node 230) is modulated by the time varying input signal V_{IN} (in the form of its sum with the common mode voltage V_{CM}) at the second biasing part 218. This causes the input signal V_{IN} to be tracked, such that a signal is provided at the output 220 of the first stage (and at first node 230) that depends on V_{IN}, i.e. such that V_{OUT1}∝(V_{CM}+V_{IN}).

The output V_{OUT1} of the first stage 200 of the track and hold circuit 100 is therefore a signal that tracks the time varying input signal V_{IN} while the clock signal CK is logic high (track mode), and which outputs a fixed voltage based on V_{CM} when the clock signal CK is logic low (hold mode).

The first stage 200 of the track and hold circuit 100 may, in some embodiments, also comprise a second section 250, in the form of a feedback loop. The feedback loop comprises two amplifiers in the form of a PMOS transistor 222 (M_{CAS}) and an NMOS transistor 224 (M_{MIR}) The transistors 222, 224 are arranged such that the second section 250 acts to compensate for variations in current draw caused by variations in the input signal. This improves linearity in the first stage 200.

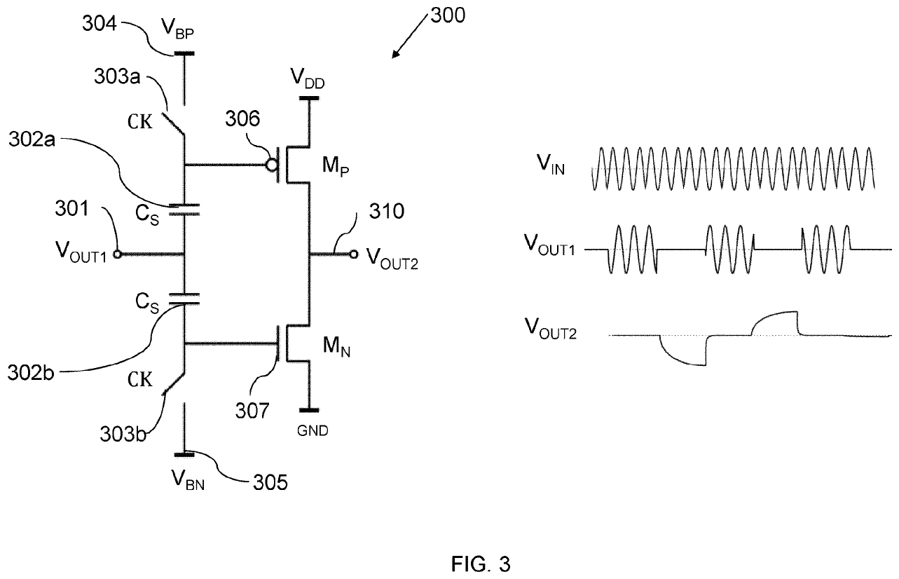

The output V_{OUT1} of the first stage 200 of the track and hold circuit 100 is provided to the second stage 300, shown in more detail in FIG. 3.

The second stage 300 of the track and hold circuit 100 comprises an input terminal 301, arranged to receive the output V_{OUT1} of the first stage 200 of the track and hold circuit 100. The input terminal 301 therefore receives a signal that tracks the time varying input signal V_{IN} while the signal CK from the clock source is logic high (track mode), and which outputs a fixed voltage based on the common mode voltage V_{CM} when the clock signal CK is logic low (hold mode).

The input terminal 301 is connected between first and second sampling capacitors 302a, 302b, each of which is connected to a respective supply rail via a respective sampling switch 303a, 303b. The first sampling capacitor 302a is connected to a first bias voltage node V_{BP} 304 by a first sampling switch 303a, and is also connected to the gate of a PMOS transistor 306. The second sampling capacitor 302b is connected to a second bias voltage node V_{BN} 305 by a second sampling switch 303b, and is also connected to the gate of an NMOS transistor 307. The respective drains of the PMOS transistor 306 and of the NMOS transistor 307 are connected to an output terminal 310, arranged to output a signal V_{OUT2} based on the respective drain-source voltages of the PMOS transistor 306 and the NMOS transistor 307. These two transistors work together to push/pull the output voltage V_{OUT2} higher or lower. As the NMOS transistor is turned more ‘off’, the PMOS transistor will be turned more ‘on’ and vice versa, thereby adjusting the current draws of both transistors in opposite ways and therefore shifting the output voltage at V_{OUT} by twice as much as if a single transistor were used. For example, as the NMOS transistor turns ‘off’ it draws less current. At the same time the PMOS transistor turns ‘on’ and it draws more current. The voltage drops across the two transistors change accordingly and the output voltage V_{OUT2} is pushed/pulled by both transistors to a new output level.

The first sampling switch 303a and the second sampling switch 303b are configured such that they can be controlled by the clock signal CK. The two switches 303a and 303b are configured to behave in the same way in response to the clock signal CK, such that at any given time both switches 303a and 303b are either open (non-conducting) or closed (conducting) simultaneously. Specifically, the first and second switches 303a, 303b are configured such that when the clock signal CK is logic high, both the first switch 303a and the second switch 303b are closed (conducting), and such that when the clock signal CK is logic low, both the first switch 303a and the second switch 303b are open (non-conducting).

When the clock signal CK is logic high, the switches 303a, 303b are closed, and the signal received at the input terminal 301, i.e. the output V_{OUT1} of the first stage 200, tracking the time varying input signal V_{IN}, is provided to the first and second sampling capacitors 302a, 302b. This causes a voltage across the first and second capacitors 302a, 302b to vary as the output of the first stage 200 of the track and hold circuit 100 varies, i.e. tracking the input signal V_{IN}. Thus, when the switches 303a, 303b are closed, the voltage across the capacitors 302a, 302b depends on the input signal V_{IN} (specifically it depends on V_{CM}+V_{IN}). In this way, the capacitors 302a, 302b track a voltage corresponding to the input signal V_{IN}, i.e. they act as a buffer that effectively stores (and continually updates during track mode) a ‘value’ (in the form of a voltage) representative of the input signal V_{IN} at any given time.

When the clock signal CK is logic low (hold mode), the signal V_{OUT1} received at the input terminal 301 is simply the fixed voltage dependent on just the common mode voltage V_{CM}. At this time, the switches 303a, 303b are configured to open as the clock signal CK transitions to the logic low state. In response to the switches 303a, 303b opening, the voltages across the capacitors 302a, 302b become fixed, causing the voltages provided at the gates of the PMOS transistor 306 and the NMOS transistor 307 to become set based on the voltage across the capacitors 302a, 302b at the time the switches 303a, 303b opened and the new reference voltage V_{OUT1} provided by the first branch of the first stage 200. This effectively provides an input at the gates of the transistors 306, 307 that contains information about the input signal V_{IN} at the time that the switches 303a, 303b were opened. The PMOS transistor 306 and the NMOS transistor 307 amplify this held signal which is received at their respective gates, and provide a voltage at the output terminal 310. An amplified signal V_{OUT2} is therefore provided at the output terminal 310 based on the bias states of the PMOS transistor 306 and the NMOS transistor 307 (and hence based on the voltage across the capacitors 302a, 302b at the time the switches 303a, 303b were opened).

During track mode, the voltage at V_{OUT1} is proportional to V_{CM}+V_{IN}, the sampling switches 303a, 303b are closed, the NMOS transistor 307 is biased by the voltage V_{BN} and the PMOS transistor 306 is biased by the voltage V_{BP} and thus the voltages across the sampling capacitors 302a, 302b are:

V₃₀₂ₐ=V_{BP}−k(V_{CM}+V_{IN})

V_{302b}=k(V_{CM}+V_{IN})−V_{BN}

where k is a proportionality constant that depends on the bias transistors 214, 218.

Then when track mode is switched to hold mode and V_{OUT1} changes to be proportional only to V_{CM}, the gates of the NMOS transistor 307 and the PMOS transistor 306 become biased based on the voltage at V_{OUT1} and the now fixed voltage across their respective sampling capacitor as:

V_{PMOS}=kV_{CM}+V₃₀₂ₐ=kV_{CM}+{V_{BP-k}(V_{CM}+V_{IN})}=V_{BP}−kV_{IN}

V_{NMOS}=iV_{CM}−V_{302b}=kV_{CM}−{k(V_{CM}+V_{IN})−V_{BN}}=V_{BN}−kV_{IN}

Using both PMOS and NMOS transistors 306, 307 advantageously provides improved gain at the output signal V_{OUT2} as the input voltage causes the gate-source voltage of one transistor to increase at the same time as the gate-source voltage of the other transistor decreases and vice-versa. Correspondingly, the drain-source voltages across one transistor increases while the drain-source voltage across the other transistor decreases and vice versa so that the effect both sampling capacitors 302a, 302b simultaneously push/pull on the output voltage V_{OUT2} for increased effect.

The second stage 300 of the track and hold circuit 100 therefore outputs a signal V_{OUT2} which is constant (based on the bias voltages V_{BP} and V_{BN}) when the clock signal CK is logic high, and which is based on the held input signal V_{IN} (held at the time that the sampling switches were opened) when the clock signal CK is logic low. As shown in FIG. 3, at high sampling rates and therefore short timescales, the output signal V_{OUT2} takes the form of a curve that begins when the switches 303a, 303b open, i.e. when the clock signal CK transitions to logic low, and which grows over time based on the held voltage across the capacitors 302a, 302b (which in turn is based on the input voltage V_{IN}) and which progresses towards a final steady state value. The curve is a result of the time it takes for the transistors 306, 307 to respond to the changed gate voltage and to settle on the new equilibrium.

The output V_{OUT2} 310 does not need to reach the steady state in order for it to be used reliable by further processing circuits as the curve will take the same form for all input voltages. Therefore, so long as the further processing circuits are timed such that they always take account of the same point in time (or portions in time) of that output signal V_{OUT2}, they will always depend to the same extent on the held input voltage. Such outputs of the track and hold output signal can therefore be readily compared relative to one another, even on short timescales.

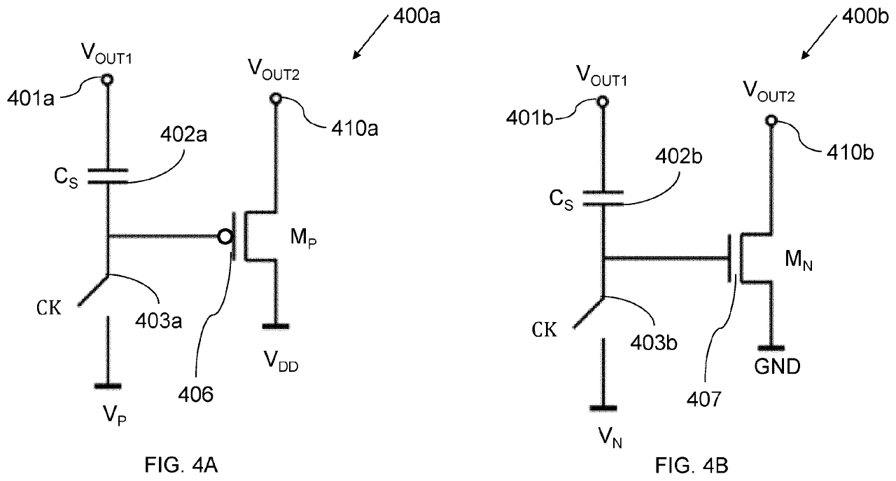

Although shown with two capacitors 302a, 302b connected to respective switches and transistors, it will be appreciated that the function of the second stage 300 of the track and hold circuit 100 may be achieved with only one of each component. Examples of this are shown in FIGS. 4A and 4B.

FIG. 4A shows a second stage 400a of the track and hold circuit according to a second embodiment of the invention. The second stage 400a comprises an input terminal 401a, arranged to receive the output V_{OUT1} of the first stage 200 of the track and hold circuit 100 shown in FIG. 2. As described above, the input signal V_{OUT1} tracks the time varying input signal V_{IN} while the signal CK from the clock source is logic high, and outputs a fixed voltage based on the common mode voltage V_{CM} when the clock signal is logic low.

The input terminal 401a is connected to a single sampling capacitor 402a, which is connected to a bias voltage supply rail V_{P} via a sampling switch 403a, and is also connected to the gate of a PMOS transistor 406. The drain of the PMOS transistor 406 is connected to an output terminal 410a, arranged to output a signal V_{OUT2} based on the output of the drain of the PMOS transistor 306.

The switch 403a is configured such that it can be controlled in response to the clock signal CK, such that when the clock signal CK is logic high, the first switch 403a is closed, and such that when the clock signal CK is logic low, the switch 403a is open. When the clock signal CK is logic high, the switch 403a is closed, and a voltage is generated across the capacitor 402a based on the signal received at the input terminal 401a and the bias voltage V_{P}. When the switch 403a is closed, a voltage is therefore generated across the capacitor 402a that depends on (and varies with) the input signal V_{IN}. The capacitor 402a therefore acts as a buffer that effectively stores a ‘value’ representative of the input signal, continually updated while the switch 403a is closed.

When the clock signal CK is logic low, the signal received at the input terminal 401a is changed so that it is based simply on the fixed common mode voltage V_{CM}. When the clock signal CK goes low, the switch 403a opens and the voltage across the capacitor 402a becomes fixed, causing the voltage at the gate of the PMOS transistor 406 to change based on the magnitude of the input signal V_{IN} at the time the switch 403a was opened (i.e. corresponding to the tracked signal immediately before the switch was opened). The PMOS transistor 406 outputs a signal at its drain based on the changed signal received at its gate, and provides this to the output terminal 410a, where it is output as V_{OUT2}.

In a similar manner to that described in relation to FIG. 3, the second stage 400a shown in FIG. 4a therefore outputs a signal V_{OUT2} which is based on the bias voltage V_{P} when the clock signal is logic high, and which changes based on the sampled input signal V_{IN} when the clock signal is logic low.

FIG. 4B shows a second stage 400b of the track and hold circuit according to a third embodiment of the invention. The second stage 400b comprises an input terminal 401b, arranged to receive the output V_{OUT1} of the first stage 200 of the track and hold circuit 100 shown in FIG. 2. The input terminal 401b is connected to a single capacitor 402b, which is connected to a bias voltage V_{N} via a switch 403b, and is also connected to the gate of an NMOS transistor 407. The drain of the NMOS transistor 407 is connected to an output terminal 410b, arranged to output a signal V_{OUT2} based on the output of the drain of the NMOS transistor 407.

The second stage 400b is therefore functionally equivalent to the second stage 400a shown in FIG. 4A, and differs only in that the PMOS transistor 406 is replaced by an NMOS transistor 407. The second stage 400b thus functions in a manner equivalent to that described above in relation to FIG. 4A, and serves to generate, at the output 410b, a signal V_{OUT2} which is based on the bias voltage V_{N} when the clock signal is logic high, and which changes based on the sampled input signal V_{IN} when the clock signal CK is logic low.

It will be appreciated by those skilled in the art that the invention has been illustrated by describing one or more specific embodiments thereof, but is not limited to these embodiments; many variations and modifications are possible, within the scope of the accompanying claims.

1. A track and hold circuit for sampling an input signal, the track and hold circuit comprising a first stage and a second stage;
wherein the track and hold circuit is arranged to operate alternately in a track mode and a hold mode;
wherein in the hold mode, the first stage is arranged to generate a constant output voltage at a first node;
wherein in the track mode, the first stage is arranged to generate the constant output voltage modulated by the input signal at the first node;
wherein the second stage comprises:
a first sampling capacitor having a first side connected to the first node and a second side connected to a first bias voltage through a first sampling switch;
wherein a first sampling output is provided at a first sampling node between the first sampling capacitor and the first sampling switch;
wherein, in the track mode, the first sampling switch is closed and the voltage across the first sampling capacitor varies as the input signal varies; and
wherein, in the hold mode, the first sampling switch is open, the voltage across the first sampling capacitor becomes fixed, and the first sampling output becomes set based on the voltage at the first node and the fixed voltage across the first sampling capacitor.

2. A track and hold circuit as claimed in claim 1, wherein the second stage comprises a second sampling capacitor having a first side connected to the first node and a second side connected to a second bias voltage through a second sampling switch;
wherein a second sampling output is provided at a second sampling node between the second sampling capacitor and the second sampling switch;
wherein, in the track mode, the second sampling switch is closed and the voltage across the second sampling capacitor varies as the input signal varies; and
wherein, in the hold mode, the second sampling switch is open, the voltage across the second sampling capacitor becomes fixed, and the second sampling output becomes set based on the voltage at the first node and the fixed voltage across the second sampling capacitor.

3. A track and hold circuit as claimed in claim 1, wherein the first sampling output is connected to a first amplifier such that the output of the first amplifier is dependent on the first sampling output; wherein the amplifier provides an output signal at a third node.

4. A track and hold circuit as claimed in claim 3, wherein the first amplifier is a first transistor, and wherein the first sampling output is connected to the gate of the first transistor.

5. A track and hold circuit as claimed in claim 3, wherein the second sampling output is connected to a second amplifier such that the output of the second amplifier is dependent on the second sampling output; wherein the second amplifier provides an output signal at the third node.

6. A track and hold circuit as claimed in claim 5, wherein the second amplifier is a second transistor, and wherein the second sampling output is connected to the gate of the second transistor.

7. A track and hold circuit as claimed in claim 2, wherein the first sampling output is connected to the gate of a PMOS transistor such that the output of the PMOS transistor at a third node is dependent on the first sampling output; and
wherein the second sampling output is connected to the gate of an NMOS transistor such that the output of the NMOS transistor at the third node is dependent on the second sampling output.

8. A track and hold circuit as claimed in claim 1, wherein the first stage comprises a first branch and a second branch, the first and second branches being current paths between a second node and the first node and being in operation alternately;
wherein the first branch is arranged to generate the constant output voltage at the first node; and
wherein the second branch is arranged to generate the constant output voltage modulated by the input signal at the first node.

9. A track and hold circuit as claimed in claim 8, wherein the first branch and the second branch are operated alternately in response to a clock signal from an external clock source.

10. A track and hold circuit as claimed in claim 9, wherein the first branch comprises a first clocking transistor, arranged to receive the clock signal at its gate and wherein the second branch comprises a second clocking transistor, arranged to receive an inverted clock signal at its gate.

11. A track and hold circuit as claimed in claim 9, wherein when the clock signal is high, the second branch is in operation, and wherein when the clock signal is low, the first branch is in operation.

12. A track and hold circuit as claimed in claim 9, wherein when the clock signal is high, the first sampling switch is closed, and wherein when the clock signal is low, the first sampling switch is open.

13. A track and hold circuit as claimed in claim 8, wherein the second node is a voltage rail or other supply of current.

14. A track and hold circuit as claimed in claim 8, wherein the second node is connected to the first branch and the second branch via a first current controlling transistor.

15. A track and hold circuit as claimed in claim 14, wherein the first current controlling transistor is a PMOS transistor, and wherein the gate of the first current controlling transistor is configured to be connected to a first biasing voltage selected to set the current through the first branch and the second branch.

16. A track and hold circuit as claimed in claim 8, wherein a current sink is connected to the first branch, the second branch and the first node via a second current controlling transistor.

17. A track and hold circuit as claimed in claim 16, wherein the second current controlling transistor is an NMOS transistor, and wherein the gate of the second current controlling transistor is configured to be connected to a second biasing voltage selected to set the current through the first branch and the second branch.

18. A track and hold circuit as claimed in claim 8, wherein the first branch comprises a first biasing part for receiving a common mode voltage.

19. A track and hold circuit as claimed in claim 18, wherein the first biasing part is a first biasing transistor connected on the first branch of the track and hold circuit and configured to receive the common mode voltage at its gate

20. A track and hold circuit as claimed in claim 8, wherein the second branch comprises a second biasing part for receiving the input signal from an external source.

21. A track and hold circuit as claimed in claim 20, wherein the second biasing part is a second biasing transistor connected on the second branch of the track and hold circuit and configured to receive the input signal at its gate.

22. A track and hold circuit as claimed in claim 21, wherein the second biasing transistor is arranged to receive the sum of a common mode voltage and the input signal at its gate.

23. A track and hold circuit as claimed in claim 1, wherein the circuit comprises a feedback element arranged to improve linearity in the first stage.

24. A track and hold circuit as claimed in claim 1, wherein the input signal is a time-varying analogue voltage.
